(19) United States
(12) Patent Application Publication
(10) Pub. No.: US 2009/0017620 A1
(43) Pub. Date: Jan. 15, 2009

(54) Method of manufacturing semiconductor device for dual damascene wiring

(75) Inventor: Yuusuke Oda, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kanagawa (JP)

(21) Appl. No.: 12/216,610

(22) Filed: Jul. 8, 2008

(30) Foreign Application Priority Data
Jul. 9, 2007 (JP) 2007-179753

(51) Int. Cl. H01L 21/768

(52) U.S. Cl. 438/666; 257/E21.585

(57) ABSTRACT

A method of manufacturing a semiconductor device includes forming a via hole in an interlayer dielectric film, forming a wiring trench in said interlayer dielectric film for connecting to the via hole, and forming a dual damascene wiring trench in the interlayer dielectric film for forming a dual damascene wiring which is connected to a conductive film. In forming the via hole, the via hole is formed in a bow shape and, in forming the wiring trench, the wiring trench is formed by etching to a position where a diameter of the via hole becomes substantially a maximum to provide a via having a forward taper shape under the wiring trench.

### BACKGROUND OF THE INVENTION

1. Field of the Invention

The present invention relates to a method for manufacturing a semiconductor device.

2. Description of Related Art

There is a via first process as shown in FIGS. 3A to 3F as one of the manufacturing processes of the dual damascene structure. As shown in FIG. 3A, for instance, a lower wiring 301, a stopper film 303, a low-permittivity film 305, a silicon oxide film 307, and an antireflection film 309 are formed, in order, over the silicon substrate (not shown in the figure). After a resist film 311 which has an opening hole at a predetermined position is formed by using a lithographic technique, a via hole 312 is formed by dry etching (FIG. 3B). Moreover, after depositing a lower resist film 313 (FIG. 3C), a low temperature oxide film 315 and an antireflection film 317 are formed thereon, in order (FIG. 3D). A resist film 319 having a predetermined pattern is formed once again (FIG. 3D) and a wiring trench 321 connected to the via hole is formed by dry etching (FIG. 3E). According to these steps, the wiring which has a dual damascene structure can be formed.

At this time, it is necessary that the size of the bottom diameter of the via be greater than a certain value in order to maintain the via resistance, EM (electro migration) tolerance, and SiV (Stress Induced Void) tolerance. On the other hand, it is necessary that the size of the top diameter during via etching be smaller than a certain value in order to maintain the ILD-TDDB (Inter-Layer Dielectrics-Time dependent Dielectric BreakDown) tolerance. In order to satisfy both, a perpendicular shape is better, where the difference between the top diameter and the bottom diameter is small after via etching.

However, when the perpendicular shaped via is formed, the opening hole diameter of the via (it is a medium diameter after via etching) is small after etching the trench. Moreover, since the side of the via is perpendicular, an overhanging structure and insufficient coverage occur after sputtering the barrier film and the seed film. As a result, via void defects may be produced during Cu plating. Specifically, in a device where the via diameter and the wiring pitch are small, the aforementioned problems are noticeable. Then, a dual damascene processing technique is required in which via void defects hardly occur and the maintenance of the ILD-TDDB tolerance is compatible with maintenance of the via resistance, the EM tolerance, and the SiV tolerance.

[Patent document 1] JP-A-2001-135724

[Patent Document 2] JP-A-Hei02(1990)-026020

[Patent Document 3] JP-A-2004-327507

[Patent Document 4] JP-A-2004-247568

[Patent Document 5] JP-A-2000-299376

[Patent Document 6] JP-A-2001-210627

In order to solve the aforementioned problems, it is effective that the via connected to the lower part of the trench wiring is formed so as to have a forward taper shape. Therefore, the deposition of the barrier seed sputter becomes better, so that via void defects hardly occur during Cu plating. FIGS. 4A to 4F show the step for forming a forward taper shaped via in the via first process. As with the above-mentioned method, after forming the resist film 311, the via hole 312 is processed so as to have a forward taper shape as shown in FIG. 4B. After that, as with the above-mentioned method, the lower resist film 313 is coated (FIG. 4C) and the trench wiring pattern is formed, and then processing the trench is performed (FIGS. 4D and 4E). As shown in FIG. 4F, since the via is formed so as to have a forward taper shape, it can be avoided that it becomes an overhang shape in a barrier sputter. As such an example, patent document 5 discloses that the trench part is processed to have a perpendicular shape and the via part is formed to have a taper shape.

However, the difference between the top diameter and the bottom diameter of the via becomes large in the forward taper shape. In the via first process where the interlayer film is thick and where processing a via having a high aspect ratio is performed, this difference becomes especially noticeable. FIGS. 5 to 7 show a wiring completion shape in the case where the via part 2 is provided at the end of the wiring trench part 1. FIG. 5 is a drawing where the perpendicular shaped via part 2 is formed in the interlayer dielectric film 3. FIG. 6 is a drawing where the forward taper shaped via part 2 is formed. As shown in FIG. 6, if the forward taper shape is obtained maintaining the same bottom diameter (b-2) as the bottom diameter (b-1) of the perpendicular shape, the top diameter thereof has to be widened during via etching. As a result, the pitch between vias becomes small at the via top part and the situation where the via top lies off the wiring occurs easily. As a result, the wiring pitch (a-2) becomes smaller, so that shorts in the wirings and deterioration of the ILD-TDDB tolerance are easily created.

On the other hand, a forward taper shaped via hole without changing the top diameter is shown in FIG. 7 in comparison with the perpendicular shape. In this case, the bottom diameter (b-3) becomes smaller. As a result, there is a fear that the via resistance increases and the SiV tolerance is deteriorated.

Moreover, a method for processing only the via part in the forward taper shape is disclosed in patent document 5. When the forward taper shape is processed, a reaction product which becomes an etching protection film is produced and etching is performed while adhering it over the side wall. However, when this reaction product increases, it makes the via etching stop and it becomes a factor in producing particles because of adhesion in the etching equipment etc. As a result, there has been a problem where a decrease in the yield is easily created.

On the other hand, patent document 1 discloses that an etching stopper film is provided between the interlayer dielectric films, thereby the via hole is formed to have a bow shape. However, the invention described in patent document 1 is one which prevents the formation of the etching residue by using the bow shape, and, as a result, the aforementioned problem has not been solved. Moreover, since the bow shape is formed by using the etching stopper film, the process is complicated.

Patent document 2 discloses that the hole can be made in a bow shape by using SiO₂ as an interlayer dielectric film and using a mixture gas of CHF₃ which has a mixture ratio of CF₄ from 30 to 70%. However, the means disclosed in patent document 2 is for forming the contact hole and similar conditions cannot be applied to the formation of the dual damascene structure. Moreover, when the interlayer dielectric film is SiOC, the control of the bow shape cannot go well only by control using a fluorine system gas.

In patent document 3, a two-step etching is performed in order to prevent the bow shape. In patent document 3, it is recognized that the bow shape is not desirable and there is no description regarding the control of the bow shape.

Patent document 4 discloses etching conditions for the low-permittivity dielectric film in order to obtain a desirable hole shape. However, there is no description for forming a via hole having a bow shape. Moreover, when it is a low-permittivity film which is being used as a damascene structure, it is difficult to process the bow shape only by controlling the mixture ratio of CF₄ and CHF₃.

Moreover, patent document 6 discloses that the SiCHO film is processed by adding N₂ gas, resulting in the etching rate being increased. However, in the document, there is no description for forming the via hole having a bow shape.

### SUMMARY OF THE INVENTION

According to an exemplary aspect of the present invention, it is a method for manufacturing a semiconductor device including the steps for forming an interlayer dielectric film composed of a material containing Si, O, and C over a conducting film formed over a semiconductor substrate, forming a via hole in the interlayer dielectric film by dry-etching using an etching gas containing a fluorocarbon system gas and N₂ gas, forming a wiring trench in said interlayer dielectric film for connecting to the via hole, and forming a dual damascene wiring trench in the interlayer dielectric film for forming a dual damascene wiring which is connected to the conducting film. Therein, the via hole is formed in a bow shape in forming the via hole, the wiring trench being formed by etching to the position of the proximity-area where the via hole becomes a maximum in forming said wiring trench, and a via having a forward taper shape is formed at the lower part of the wiring trench.

According to the exemplary aspect of the present invention, the bottom diameter of the via may be maintained at a certain value or more by forming the via hole to have a bow shape and the top diameter of the via is made a certain value or less. According to the structure, it becomes possible to provide a semiconductor device where the via resistance is suppressed, the EM tolerance and the SiV tolerance maintained, and the ILD-TDDB tolerance maintained.

According to the exemplary aspect of the present invention, the via hole can be controlled to have a bow shape in forming the dual damascene structure. According to the structure, a semiconductor device is provided where the via resistance is suppressed, the EM tolerance and the SiV tolerance maintained, and the ILD-TDDB tolerance maintained.

### BRIEF DESCRIPTION OF THE DRAWINGS

The above and other exemplary aspects, advantages and features of the present invention will be more apparent from the following description of certain exemplary embodiments taken in conjunction with the accompanying drawings, in which:

FIGS. 1A to 1E are cross-sectional drawings illustrating the respective processes for manufacturing a semiconductor device of an exemplary embodiment;

FIG. 2 is a schematic cross-sectional drawing illustrating a via having a bow shape formed in the exemplary embodiment;

FIGS. 3A to 3F are cross-sectional drawings illustrating the respective processes for manufacturing a perpendicular shaped via of a related art;

FIGS. 4A to 4F are cross-sectional drawings illustrating the respective processes for manufacturing a taper shaped via of a related art;

FIG. 5 is a cross-sectional drawing illustrating a wiring including an adjacent perpendicular shaped via part;

FIG. 6 is a cross-sectional drawing illustrating a wiring including an adjacent taper shaped via part;

FIG. 7 is a cross-sectional drawing illustrating a wiring including an adjacent taper shaped via part;

FIG. 8 is a cross-sectional drawing illustrating a wiring including an adjacent bow shaped via part relating to the exemplary embodiment of the present invention;

FIG. 9 is a graph where the dependence of the amount of bow (c/d) on the N₂ gas flow rate is shown; and

FIG. 10 is a graph where the dependence of the amount of bow (c/d) on the hole size (d) is shown.

### DETAILED DESCRIPTION OF THE EXEMPLARY EMBODIMENTS

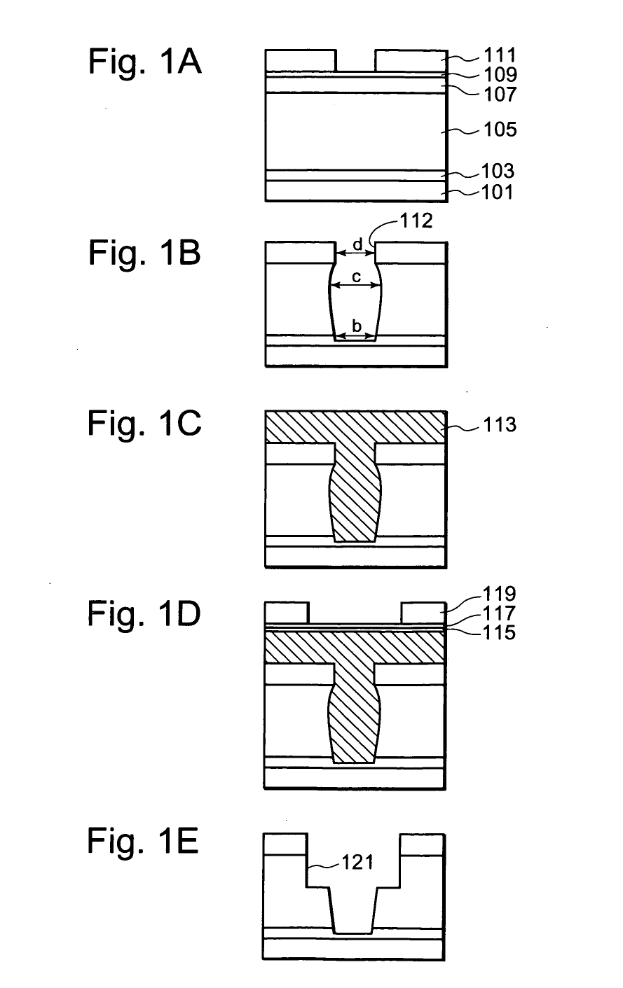

FIGS. 1A to 1F are drawings illustrating a process for manufacturing a semiconductor device of an exemplary embodiment. In this embodiment, a wiring trench having a dual damascene structure is formed.

First of all, a lower conducting film 101 is formed over a silicon substrate (not shown in the figure). Something other than a silicon substrate may also be used for a semiconductor substrate. The lower conducting film 101 includes, for instance, a barrier metal and a conducting film containing copper. The conducting film containing copper has a material including copper as a main component.

Next, an interlayer dielectric film 105 includes a material containing Si, O, and C is formed over the lower conducting film 101. For instance, a stopper film 103 is formed, and an interlayer dielectric film 105, a silicon oxide film 107, and an antireflection film 109 are formed thereon, in order. For instance, SiCN, SiC, and SiON, etc. are used as the stopper film 103.

As the interlayer dielectric film 105 including a material containing Si, O, and C, a low-permittivity material is used and, for instance, it is a carbon containing silicon oxide film (SiOC film). Such a low-permittivity material is effective for decreasing the parasitic capacitance. Moreover, in this embodiment, a via hole having a good bow shape can be stably formed in the interlayer dielectric film containing such a low-permittivity material.

Then, a resist is coated and pattering the via is performed by exposure. As a result, a resist film 111 is formed which has an opening hole at a predetermined position. (FIG. 1A). In this embodiment, the hole diameter is, for instance, 110 nm or more and 190 nm or less.

Next, as shown in FIG. 1B, the resist film 111 is used as a mask and the via hole is formed by dry-etching. In this embodiment, etching is performed under the conditions where the via becomes a bow shape. For instance, using two-frequency RIE equipment, the via hole 112 having a desired bow shape is formed by dry-etching using an etching gas containing a fluorocarbon system gas and N₂ gas. Afterwards, the resist is removed by ashing.

Next, the via hole 112 is embedded by coating the lower resist 113 (FIG. 1C). A low temperature oxide film 115 and an antireflection film 117 are formed over the entire surface of the lower resist 113. Then, a resist film 119 is coated and a resist film 119 having an opening hole at a predetermined position is formed by using a lithography technique (FIG. 1D).

After that, a wiring trench 121 connected to the via hole is formed by dry-etching. The wiring trench 121 is a dual damascene wiring trench for forming the dual damascene wiring connected to the lower conducting film 101.

In this embodiment, the wiring trench 121 is formed by etching to the position of the proximity-area where the via hole becomes a maximum in the step for forming the wiring trench, and a forward taper shaped via is formed at the lower part of the wiring trench 121 (FIG. 1E). Preferably, the relationship between the bow part of the via and the bottom part of the trench is made such that the bottom part of the trench is lower than the bow part. The upper part of the bow shape is formed to be a part of the wiring trench by wiring trench etching, so that the residual via part can be formed in a taper shape suitable for embedding. Thus, a dual damascene wiring can be formed in which the bottom diameter of the via is maintained at a certain value or more and the top diameter of the via is maintained at a certain value or less. The etching to the position of the proximity-area where the via hole becomes a maximum is performed by a time control, which are determined by an etching time calculated based on a data of an etching rate and the etching depth of an interlayer insulating film, previously measured. The etching of via hole and the trench may be performed in the same etching chamber.

In this embodiment, the bow shape used for the via means a shape where the position of the maximum diameter of the cross-section of the via is located at the middle position in the depth direction of the via and the cross-sectional shape of the via becomes smaller from the position having a maximum diameter thereof to the upper part and the lower part. For instance, in FIG. 1B, if d is the via top diameter (opening hole diameter), c the via maximum diameter located at the position between the via top and bottom (bow part), and d the via bottom diameter, it is a shape such that d<c and c>b.

In this embodiment, the preferable range of the amount of bow (c/d) which is expressed as a ratio of the top diameter d and the bow part c of the via is, for instance, 1.03≦c/d≦1.1. If the amount of bow is in the aforementioned range, then it is preferable because the bow shape is maintained. Moreover, it is preferable that the amount of bow be lower than the aforementioned upper limit from the viewpoint of preventing short-circuits of the bow part.

In the aforementioned process, the bow shaped via hole is formed in one step in the embodiment. In patent document 1, the process is complicated because a trench etching stopper film is used. Moreover, in the structure without a trench stopper, it is difficult to perform etching for over-etching in patent document 1 and to form the bow shaped via. Therefore, the conditions described in patent document 1 cannot be similarly applied to the trench stopper-less structure in this embodiment. On the other hand, since the trench etching stopper film, etc. is not used in this embodiment, it is a lower cost process and the process thereof is easy.

Moreover, in this embodiment, the via hole is controlled to have a bow shape and the via diameter can be controlled in the depth direction.

In this embodiment, the control of the bow shape and the via diameter in the depth direction of the via can be achieved by controlling various conditions such as the etching gas, the stage temperature, the temperature of the etching gas, and the hole size of the resist film, etc. Concretely, the bow shape of the via can be achieved by properly controlling the various factors described below.

In this embodiment, a mixture gas containing a fluorocarbon system gas and N₂ gas is used as an etching gas. For instance, as a fluorocarbon, a compound shown as CₙHₘF₂ₙ₋ₘ₊₂(n and m are integers) can be used. Such a fluorocarbon includes CHF₃, C₃F₈, and CF₄, etc. In this embodiment, a mixture gas of CF₄ and CHF₃ can be used as a fluorocarbon system gas.

In this embodiment, the ratio of the gas flow rate of the fluorocarbon system gas is, for instance, 2% or more and 10% or less of the total flow rate of the etching gas. Moreover, the gas flow rate of the fluorocarbon system gas is, for instance, 20 sccm or more and 100 sccm or less.

Further control of the amount of bow is possible by controlling the N₂ gas flow rate. For instance, the bow shape may be controlled by making the gas flow rate of N₂ 170 sccm or more and 350 sccm or less, preferably 170 sccm or more and 220 sccm or less. If the N₂ gas flow rate is in the aforementioned range, a via hole having a preferable bow shape can be formed.

Herein, if the N₂ gas flow rate is too low, then the via hole becomes a taper shape and there is a possibility that the bow shape is not formed. Therefore, if the N₂ gas flow rate is the aforementioned lower limit or more, then a preferable bow shape can be formed. Moreover, if the adjacent wirings do not exist, then a problem never happens in which the bow shaped via holes approach each other too close. Therefore, since there is no danger of a short circuit, the upper limit of the N₂ gas flow rate is not specifically limited. However, if the N₂ gas flow rate is too high, then an etching stop occurs depending on the location of the wafer. As a result, in-plane inhomogeneity of the etch rate occur and there is a case that a problem may arise in the yield. Therefore, it is preferable that the N₂ gas flow rate be the aforementioned upper limit or less.

Moreover, the bow shape may be controlled to make the ratio of the N₂ gas flow rate 15% or more and 25% or less against the total flow rate of the etching gas. If the ratio of the N₂ gas flow rate is in the aforementioned range, then a preferable bow shaped via hole can be formed.

Herein, if the ratio of the N₂ gas flow rate is too low, then the via hole becomes a taper shape and there is a possibility that the bow shape is not formed. Therefore, if the ratio of the N₂ gas flow rate is the aforementioned lower limit or more, then a preferable bow shape can be formed. Moreover, if the adjacent wirings do not exist, a problem never happens in which the bow shaped via holes approach each other too close. Therefore, since there is no danger of a short circuit, the upper limit of the ratio of the N₂ gas flow rate is not specifically limited. However, if the N₂ gas flow rate is too high, then etching stop occurs depending on the location of the wafer. As a result, in-plane inhomogeneity of the etch rate occurs and there is a case that a problem may arise in the yield. Therefore, it is preferable that the ratio of the N₂ gas flow rate be the aforementioned upper limit or less.

Furthermore, the position where the bow is inserted in the depth direction of the via can be controlled by the stage temperature. The preferable temperature range is not limited but, for instance, it is 0° C. or more and 40° C. or less.

Moreover, in a range where the effects of this embodiment are not lost, the etching gas may contain other gases in addition to the aforementioned gases, for instance, an inert gas, etc. As an inert gas, Ar and He, etc. can be used.

Moreover, the stage temperature is not limited but, preferably, it is 0° C. or more and 40° C. or less. A preferable bow shaped via hole can be formed in such a range. Furthermore, the position where the bow is inserted in the depth direction of the via can be controlled by the stage temperature. The control of the position where the bow is inserted is not limited. However, it is preferable that it be performed in the aforementioned temperature range.

The bow shape is generally formed through the following processes. First, during etching, a carbon-rich deposit is adhered, concentrating around the front of the hole. When the amount of such a deposit is increased, the deposit hardly comes inside the hole thereunder. Therefore, a part may be created where the deposit becomes thinner. The part where the deposit is thinner is radically etched and etching proceeds in a horizontal direction, resulting in the bow shape being formed. Herein, if the stage temperature is too low, there is a possibility that the amount of carbon rich deposit adhering around the front of the hole increases too much. As a result, there is a possibility that etch stop occurs by inhibiting etching and a problem may arise in the yield. On the other hand, with an increase in the stage temperature, the adhesion coefficient of the carbon rich deposit which adheres to the front of the hole decreases. Therefore, the degree to which the deposit concentrated around the front decreases and the position where the deposit is concentrated becomes lower. As a result, the position of the bow becomes lower. The control of the position where the bow is inserted can be controlled by using such a means. However, if the stage temperature is too high, then a carbon rich deposit does not adhere easily by being concentrated. In addition, there is a possibility that the bow shape is not formed and it is preferable that the stage temperature be controlled to be lower than a certain temperature.

Moreover, the amount of bow can be also controlled by the hole size (opening hole diameter) of the via. The preferable hole size is not especially limited, but, for instance, it is 110 nm or more and 190 nm or less. However, in order to obtain a bottom diameter of a certain value or more, the preferable hole size is 140 nm or more and 190 nm or less.

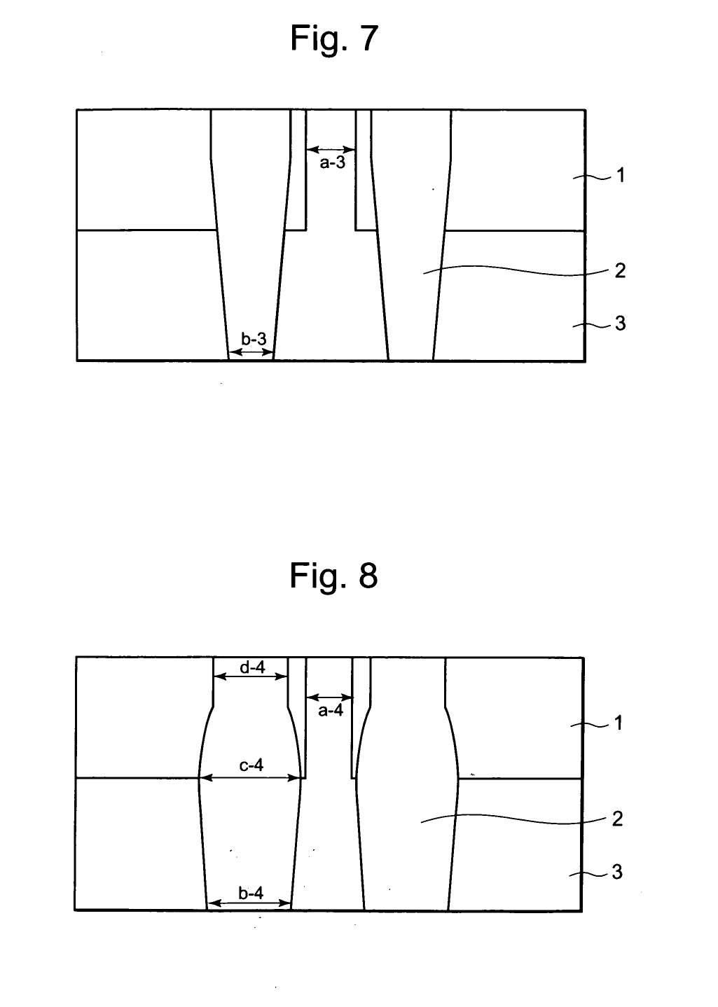

In this embodiment, the upper part of the formed bow shaped via hole finally becomes a wiring trench 1. Therefore, when the wiring trench connected to the via hole is formed, the shape of the via part 2 finally becomes a preferable taper shape. In this embodiment, the top diameter (d-4) of the via (FIG. 8) is smaller in the case where it is made in a taper shape while maintaining the bottom diameter (b-2) of the via (FIG. 6). Moreover, the opening hole diameter of the via (c-4) after etching the wiring trench can be made almost the same size as the case where the via is made in a taper shape. As shown in FIG. 8, the via part 2 has a side wall which is a curvature between its bottom b-4 and is opening hole diameter c-4, on the contrary to the structure shown in FIGS. 6 and 7, which show the via part 2 has substantially straight side walls. Therefore, a via shape can be obtained in which via void defects hardly occur, so that it becomes possible to satisfy both the requirement of the maintenance of the ILD-TDDB tolerance where it is desired that the top diameter be smaller and the requirement of the maintenance of the via resistance and the maintenance of the EM tolerance and the SiV tolerance where it is desired that the bottom diameter of the via be larger.

Moreover, since dry etching of the bow shape in this embodiment is performed under the conditions where the side wall protection is made weaker than etching of the taper shape, the amount of the reaction products can be decreased during etching. As a result, it is possible to make it difficult for etching stop due to the creation of a large amount of reaction products and a decrease in the yield caused by the creation of particles to occur.

### EXAMPLE 1 OF THE PRESENT INVENTION

According to a method similar to that of the aforementioned embodiment, a bow shaped via hole was formed. In this example, a via hole was formed by using a N₂ gas flow rate condition of 180 sccm. The structure and the etching conditions, etc. for the interlayer dielectric film are as follows.

### (Interlayer Dielectric Film)

Stopper film: SiCN (thickness of 50 nm)

Interlayer dielectric film: SiOC (thickness of 400 nm)

Silicon oxide prevention film: (thickness of 180 nm)

### (Etching Conditions)

Using two-frequency RIE equipment and the following conditions, a bow shape was obtained.

Size of target hole: 170 nm

Etching gas: CF₄ 30 sccm, CHF₃ 30 sccm, Ar 1000 sccm, and N₂ 180 sccm

Conditions: the input power of the upper part 2000 W, the input power of the lower part Bias 2000 W, the stage temperature 20° C.

### COMPARATIVE EXAMPLE 1

Except for changing the N₂ gas flow rate condition to 60 sccm, a via hole was formed by using the same conditions as example.

### COMPARATIVE EXAMPLE 2

Except for changing the N₂ gas flow rate condition to 120 sccm, a via hole was formed by using the same conditions as example.

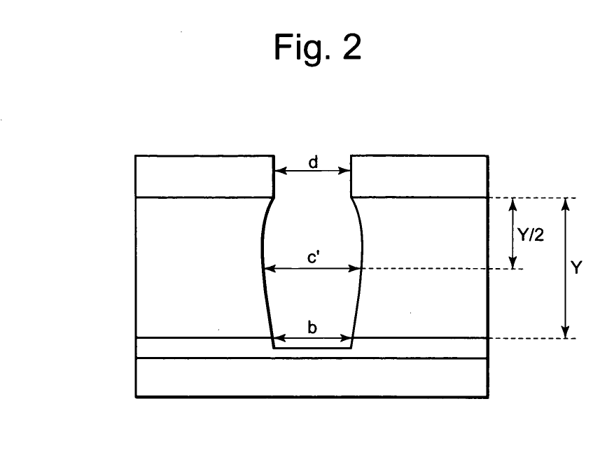

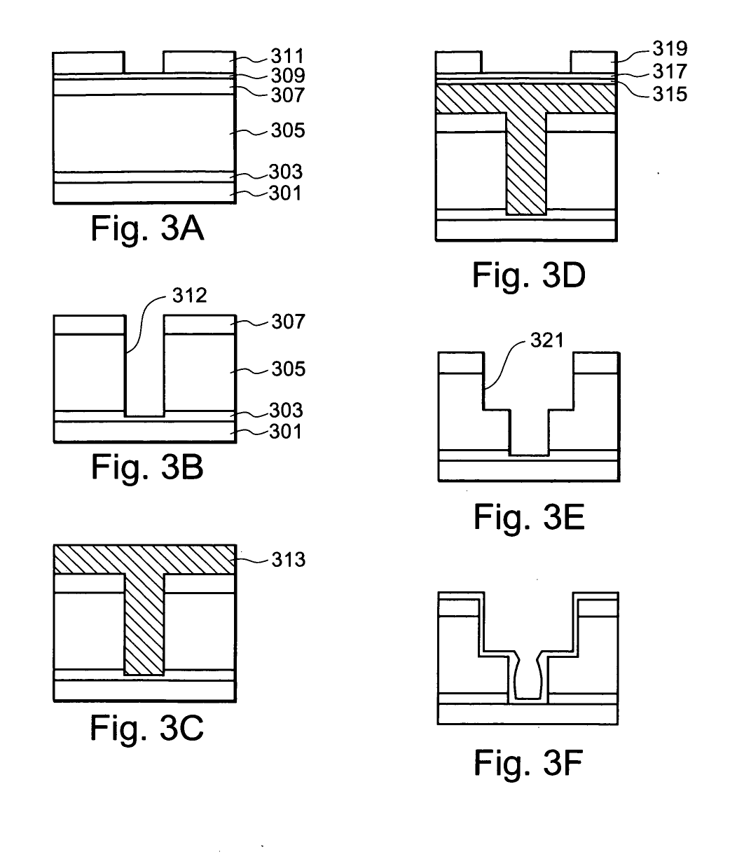

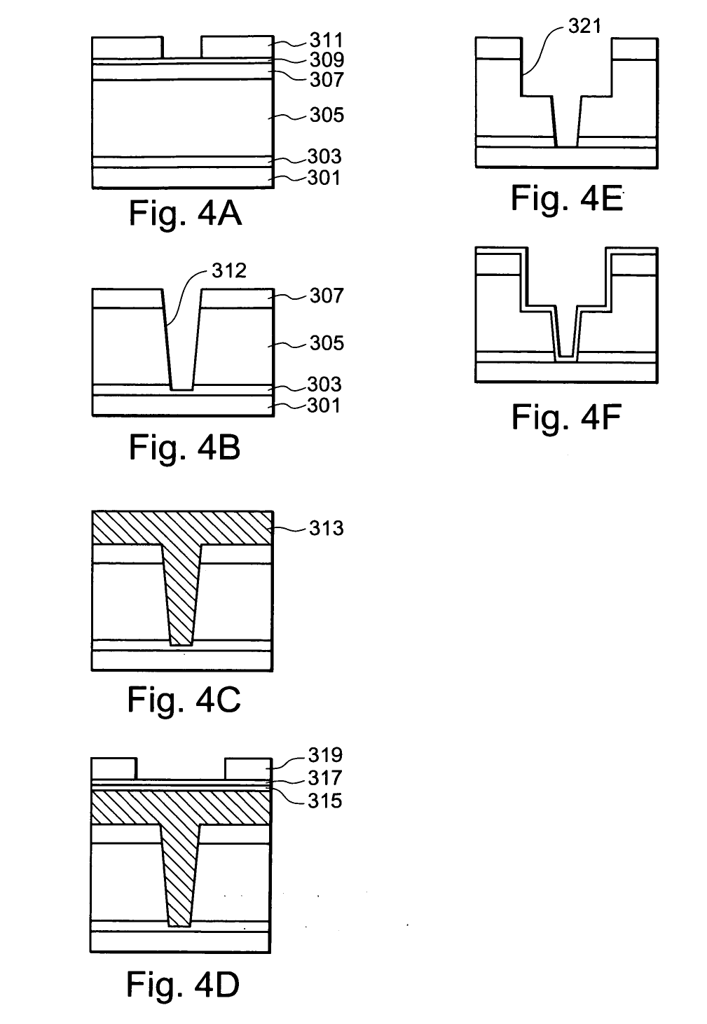

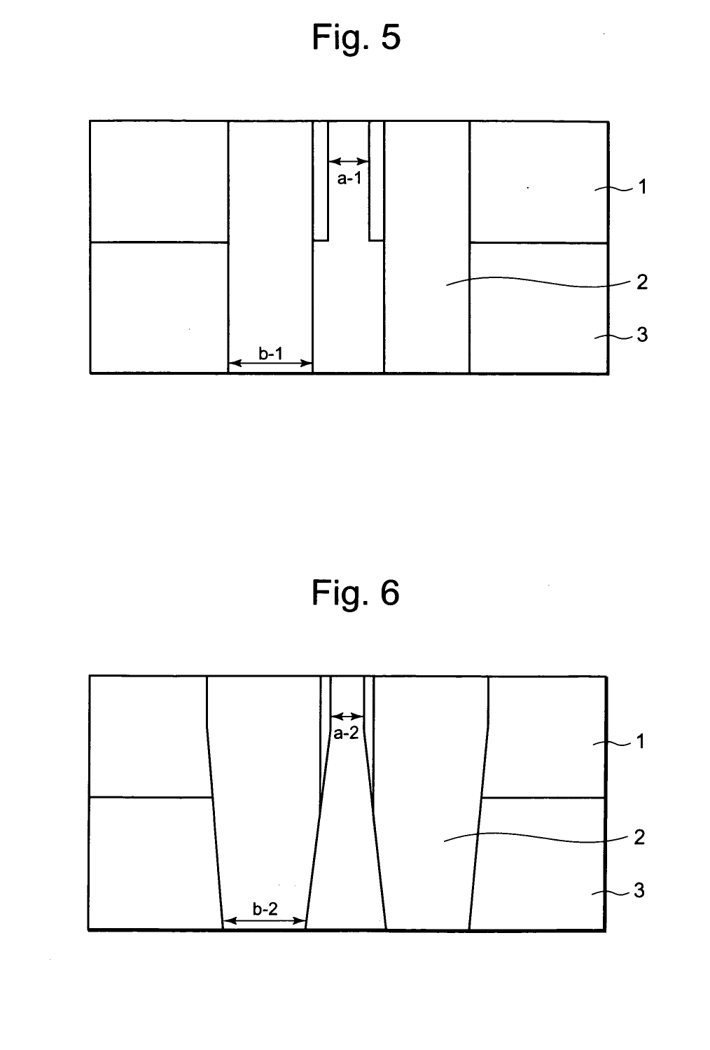

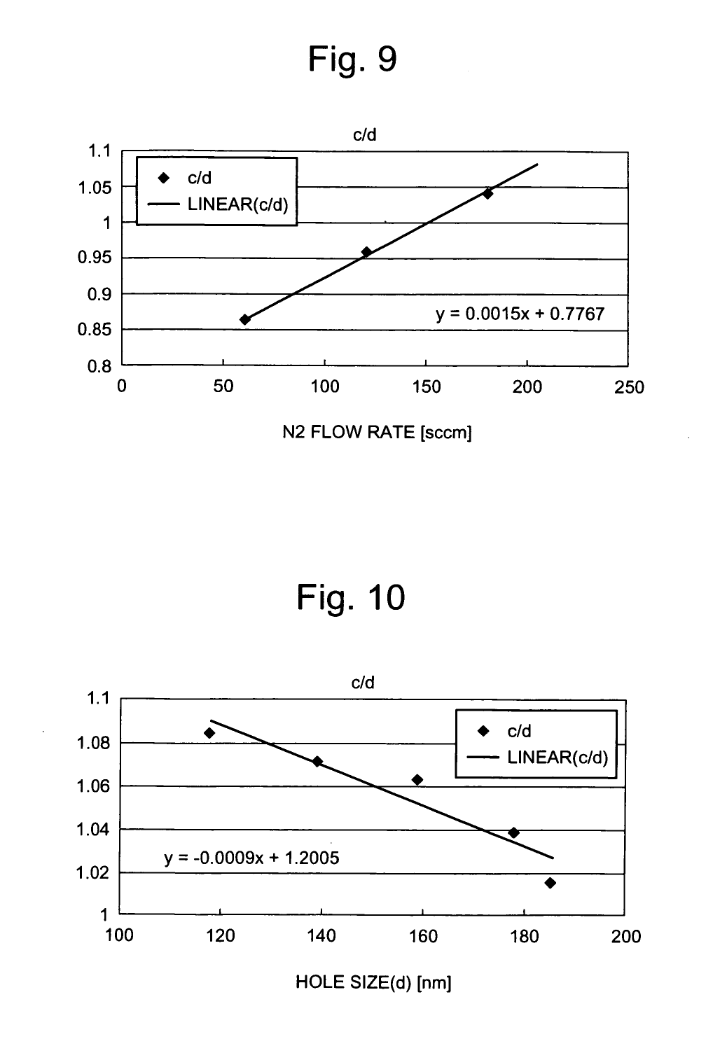

In the aforementioned examples, the dependence of the amount of the bow on the N₂ gas flow rate was studied after forming the via hole. In FIG. 9, the dependence of the amount of the bow on the N₂ gas flow rate is shown when the target hole size (d) is 170 nm. The vertical axis indicates the amount of bow (c/d) and the N₂ gas flow rate (sccm). In the example and the comparative example, the amount of bow (c/d) is expressed as the ratio of the via maximum diameter c and the via top diameter d as shown in FIG. 2. The maximum diameter c of the via is calculated by assuming c′ which is the via diameter at the middle position of the interlayer dielectric film in the thickness direction, that is, the position of Y/2, when the thickness of the interlayer dielectric film is Y. When the preferable region of the amount of bow (c/d) is controlled to be 1.03≦c/d≦1.1, a preferable bow shaped via was formed in example. Moreover, as shown in FIG. 9, using the conditions of the target hole size (d) of 170 nm and under the conditions used in this example and the comparative examples, a preferable amount of bow could be achieved in the range from 170 sccm to 220 sccm of the N₂ gas flow rate.

### EXAMPLE 2

Except for changing the N₂ gas flow rate to 180 sccm and using various hole sizes, a bow shaped via hole was formed by using the same conditions as example 1. In this embodiment, the hole sizes of 120 nm, 140 nm, 160 nm, 180 nm, and 190 nm were used.

According to the results of the example, the dependence of the amount of bow on the hole size (d) was studied when the N₂ flow rate was 180 sccm. FIG. 10 shows the change of the amount of bow depending on the hole size (d). According to FIG. 10, the amount of bow in a preferable range was achieved in each hole size of 120 nm, 140 nm, 160 nm, 180 nm, and 190 nm under the etching conditions used in the example.

While the invention has been described in terms of several exemplary embodiments, those skilled in the art will recognize that the invention can be practiced with modification within the spirit and scope of the appended claims.

Further, it is noted that Applicant's intent is to encompass equivalents of all claim elements, even if amended later during prosecution.

What is claimed is:

1. A method of manufacturing a semiconductor device, comprising:
forming an interlayer dielectric film containing a material which has silicon, oxide, and carbon over a conductive film, said conductive film being formed over a semiconductor substrate;
forming a via hole having a bow shape in said interlayer dielectric film by dry-etching using an etching gas containing a fluorocarbon-based gas and N₂ gas; and
forming a wiring trench in said interlayer dielectric film for connecting to said via hole to provide a dual damascene wiring trench in said interlayer dielectric film for forming a dual damascene wiring connected to said conductive film, by etching said via hole to a position where a diameter of said via hole becomes substantially a maximum.

2. The method according to claim 1,
wherein a ratio between an opening hole diameter d of said via hole before said forming of said wiring trench and the maximum diameter c of said via hole is substantially in a range of 1.03≦c/d≦1.1.

3. The method according to claim 1,
wherein a flow rate of said N₂ gas is within a range of substantially 170 sccm or more and substantially 350 sccm or less.

4. The method according to claim 1,
wherein a ratio of a flow rate of said N₂ gas to a total flow rate of the etching gas is within a range of substantially 15% or more and substantially 25% or less.

5. The method according to claim 1,
wherein an opening hole diameter d of said via hole is in a range of substantially 110 nm or more and substantially 190 nm or less before said forming of said wiring trench.

6. The method according to claim 1,
wherein a stage temperature is within a range of substantially 0° C. or more and substantially 40° C. or less in said forming of the via hole.

7. The method as claimed in claim 1, wherein said via after said forming of said wiring trench has a forward taper shape under said wiring trench.

8. The method as claimed in claim 1, wherein said via after said forming of said wiring trench has a curvature side wall from under said wiring trench to a bottom of said via.

9. A method of manufacturing a semiconductor device, comprising:
forming an interlayer dielectric film over a conductive film, said conductive film being formed over a semiconductor substrate;
forming a via hole having a bow shape in said interlayer dielectric film; and
forming a wiring trench in said interlayer dielectric film for connecting to said via hole, to provide a dual damascene wiring trench in said interlayer dielectric film for forming a dual damascene wiring connected to said conductive film, by etching said via hole to a position where a diameter of said via hole becomes substantially a maximum.

10. The method according to claim 9,
wherein a ratio between an opening hole diameter d of said via hole before said forming of said wiring trench and the maximum diameter c of said via hole is substantially in a range of 1.03≦c/d≦1.1.

11. The method according to claim 9,
wherein a flow rate of said N₂ gas is within a range of substantially 170 sccm or more and substantially 350 sccm or less.

12. The method according to claim 9,
wherein a ratio of a flow rate of said N₂ gas to a total flow rate of the etching gas is within a range of substantially 15% or more and substantially 25% or less.

13. The method according to claim 9,
wherein an opening hole diameter d of said via hole is in a range of substantially 110 nm or more and substantially 190 nm or less before said forming of said wiring trench.

14. The method according to claim 9,
wherein a stage temperature is within a range of substantially 0° C. or more and substantially 40° C. or less in said forming of the via hole.

15. The method as claimed in claim 9, wherein said via after said forming of said wiring trench has a forward taper shape under said wiring trench.

16. The method as claimed in claim 9, wherein said via after said forming of said wiring trench has a curvature side wall from under said wiring trench to a bottom of said via.
